(19) United States
(12) Patent Application Publication
(10) Pub. No.: US 2007/0155097 A1
(43) Pub. Date: Jul. 5, 2007

(54) Method for fabricating flash memory device

(75) Inventors: Ji Hyung Yune, Seoul (KR); Young Wook Shin, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/641,793

(22) Filed: Dec. 20, 2006

(30) Foreign Application Priority Data
Dec. 29, 2005 (KR) 10-2005-0133440

(51) Int. Cl. H01L 21/336

(52) U.S. Cl. 438/257

(57) ABSTRACT

A method for fabricating a flash memory device includes the steps of forming a buffer film on a semiconductor substrate having a defined active region; controlling a threshold voltage of a memory cell by ion-implanting dopants into the active region of the substrate under the buffer film; removing the buffer film by performing a wet-cleaning process whose target thickness is about 1 to about 1.5 times the buffer film thickness; and forming a tunnel dielectric film on the active region of the exposed substrate after the buffer film is removed.

### FIELD OF THE INVENTION

The present invention relates to a semiconductor device fabrication technology, and more specifically, to a method for fabricating a flash memory device.

### BACKGROUND OF THE INVENTION

Flash memory is a kind of PROM (Programmable ROM), capable of rewriting data electrically. The flash memory performs both a program input method of EPROM (Erasable PROM) and an erasing method of EEPROM (Electrically Erasable PROM) with one transistor. EPROM has a small cell area (in that, its memory cell is composed of 1 transistor) and needs a lump erasure with ultraviolet rays. EEPROM can be electrically erasable, but has a relatively larger cell area (in that, its cell is composed of 2 transistors). Combining the merits of both EPROM and EEPROM results in what is known as flash memory, or more correctly known as Flash EEPROM. Flash memory is also commonly referred to as a nonvolatile memory because its memory information is not erased (even when powered off), which differentiates it from DRAM (Dynamic RAM) and SRAM (Static RAM).

Flash memory can be classified according to a cell array scheme, that is, a NOR type structure where the cell is arranged in parallel between a bit line and a ground, and a NAND type structure where the cell is serially arranged between them. The NOR type flash memory having a parallel scheme is generally used to boot mobile phones since it can make a high speed random access when used in a reading operation. The NAND type flash memory having a serial scheme is attractive as a means for general data storage because its writing speed is high (although its reading speed is low) and it can be miniaturized with ease. Further, flash memory can be divided into a stack gate type and a split gate type according to the unit cell structure, and divided into a floating gate device and SONOS (Silicon-Oxide-Nitride-Oxide-Silicon) device according to the charge storage layer type.

The general concepts of a unit memory cell structure of a floating gate device are shown in FIG. 1. The floating gate device includes a floating gate 16 formed of polycrystalline silicon, which is enclosed with a dielectric 18 (having an ONO structure composed of oxide-nitride-oxide, generally). Charge is injected or discharged into or from a floating gate 16 by Channel Hot Carrier Injection or F-N (Fowler-Nordheim) tunneling, so that data storage and erasure are achieved. In memory operations, in order to keep the floating gate charged, a special oxide film referred to as a tunnel oxide 14 is used between the substrate 10 and the floating gate 16. The tunnel oxide film 14 plays a very important role in the flash memory device.

Processes to fabricate the flash memory device comprise the general steps of forming a buffer oxide film on the substrate 10, performing an ion-implantation process to control a threshold voltage of a cell, removing the buffer oxide film and, at the same time, cleaning the substrate 10, forming the tunnel oxide 14 on the substrate 10, forming the floating gate 16, forming an inter-gate insulation film 18, forming a control gate 20 to constitute a word line, and forming source/drain diffusion regions 12s and 12d into the substrate 10.

The flash memory device is designed to have a useful life of more than 10 years and/or be capable of recording/erasing more than 1 million times. It is believed that one critical factor affecting the performance of flash memory is whether the word line is faulty or not. The fault of the word line may be induced by a variety of factors, and particularly, the determination whether faulty or not depends on many parameters of processes. Accordingly, it can be said that in order to enhance yields and reliability of the flash memory device it is important to improve the fault of the word line.

### SUMMARY OF THE INVENTION

In accordance with one preferred embodiment of the present invention, there is provided a method for fabricating a flash memory device, comprising forming a buffer film on a semiconductor substrate with a defined active region; controlling a threshold voltage of a memory cell preferably by ion-implanting dopants into the active region of the substrate under the buffer film; removing the buffer film preferably by performing a wet cleaning process whose target thickness is preferably about 1 to about 1.5 times the buffer film thickness; and forming a tunnel dielectric film on the active region of the exposed substrate after the buffer film is removed.

In one preferred embodiment, when the buffer film is removed, a portion of the substrate also may be removed together with the buffer film. More preferably, the target thickness of the wet-cleaning process may be about 1.4 times the buffer film thickness. Further, the semiconductor substrate may be formed of silicon, and the buffer film and the tunnel dielectric film may be formed of a silicon oxide film.

It is an object of the present invention to provide a method for improving faults of a word line in a flash memory device.

Another object of the present invention is to provide a method for safely removing from a semiconductor substrate a buffer oxide film used in an ion implantation process to control a threshold voltage of a memory cell.

### BRIEF DESCRIPTION OF THE DRAWINGS

The above and other objects and features of the present invention will become apparent from the following description of preferred embodiments given in conjunction with the accompanying drawings, in which:

FIG. 1 is a sectional view showing a conventional flash memory device;

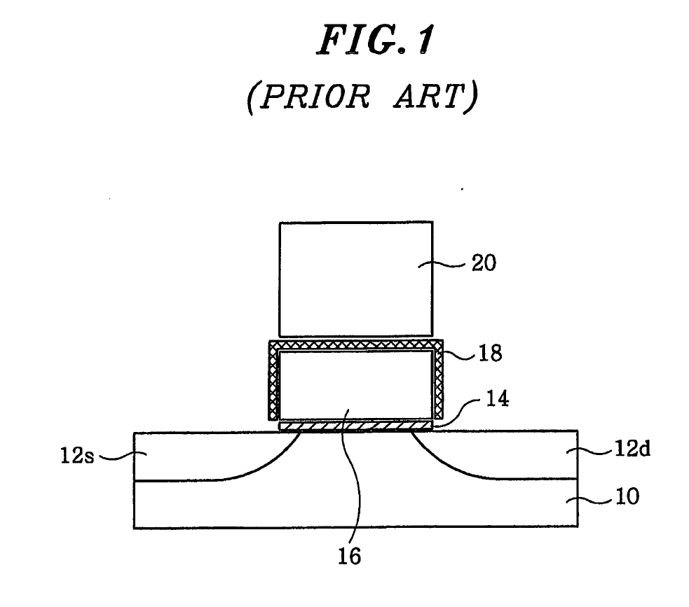

FIG. 2 shows yields and a word line fault ratio of flash memory devices fabricated according to a conventional method as time lapses; and

FIG. 3 is a graph comparatively showing a fault ratio of a flash memory device to which a pre-cleaning process in accordance with one embodiment of the present invention is performed and that of a flash memory device to which a pre-cleaning process in accordance with a conventional method is performed.

### DETAILED DESCRIPTION OF THE PREFERRED EMBODIMENTS

Hereinafter, a preferred embodiment of a method for fabricating a flash memory device in accordance with the present invention will be described in detail with reference to the accompanying drawings so that it can be readily performed by those skilled in the art.

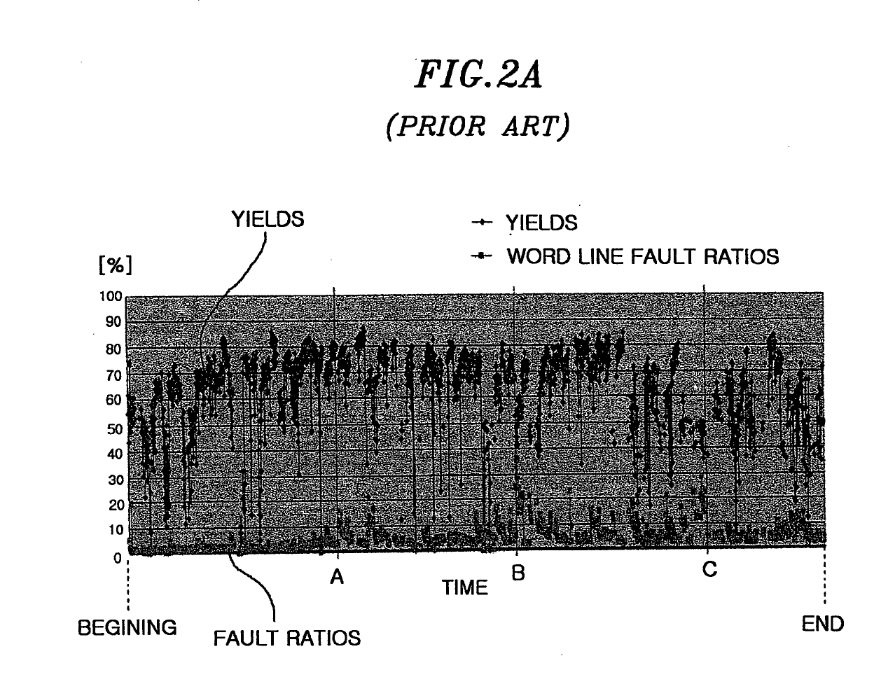

First, referring to FIG. 2, a cause for a word line fault of a flash memory device fabricated by a conventional method will be described.

FIG. 2 shows yields and a word line fault ratio of flash memory devices measured by repeated experiments for program/erasure operations after manufacturing a plurality of devices using a conventional method. The X-axis denotes lapsed time of about 4 months from beginning to end of the experiment, and Y-axis denotes the yields (%) or the word line fault ratio (%). It should be noted that the fault ratio sharply increases at periods A, B and C.

It is believed that the increase of the word line fault ratio is caused by substrate damage induced in a pre-cleaning process performed before the tunnel oxide film is formed. FIG. 2 shows a word line fault ratio of a flash memory device measured when the pre-cleaning process is performed on a buffer oxide film having a thickness of about 100 Å, with an assumption that the target thickness of the pre-cleaning process is about 200 Å. As will be described later, the word line fault ratio can be reduced by changing the target of the pre-cleaning process.

According to the method for fabricating the flash memory device in accordance with one embodiment of the present invention, a silicon oxide film is formed as a buffer film on a silicon substrate whose active region is defined by forming a plurality of device isolation films. The silicon oxide film, which may be used as the buffer film, can be formed by a chemical vapor deposition process.

A threshold voltage of the memory cell is controlled by ion-implanting dopants into the substrate which has the buffer film formed thereon. After controlling the voltage and before forming the tunnel dielectric film arranged between the substrate and the floating gate, the buffer film is removed and, at the same time, a pre-cleaning process to clean the surface of the substrate is performed.

The pre-cleaning process may be preferably performed using a wet cleaning liquid, wherein the buffer film is preferably removed using DHF (Dilute HF) having H₂O and HF mixed. The impurities may be removed using a COM cleaning process. Here, the COM cleaning process may be preferably performed by processing the substrate with about 4% HCl for about 180 seconds and then, with ozone water (about 5 ppm ozone) for 600 seconds.

The preferable target thickness of the pre-cleaning process for this embodiment may be set from about 1 to about 1.5 times the buffer film thickness. If the buffer film is a silicon oxide film of 100 Å and the target thickness is set from 100 Å to 150 Å in the pre-cleaning process, a small amount of silicon on the substrate surface also can be removed together with the buffer film.

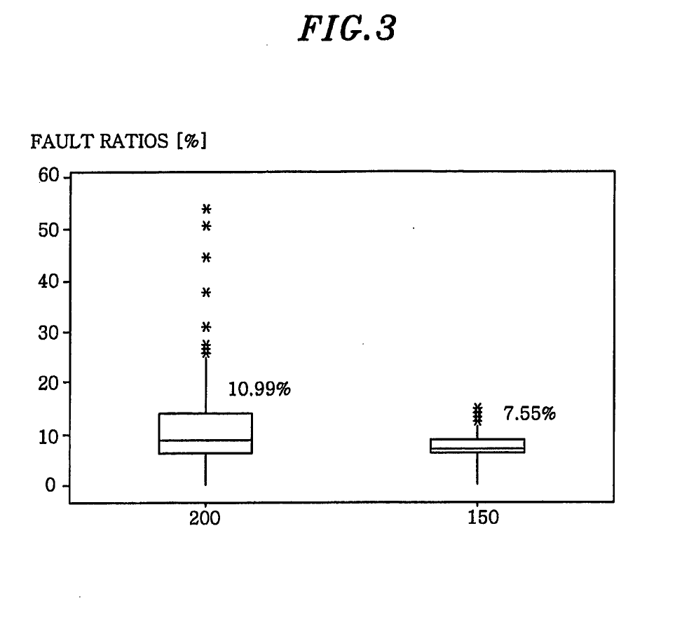

FIG. 3 comparatively shows word line fault ratios with respect to the cases that the target thicknesses of the pre-cleaning process are set 200 Å and 150 Å, respectively, when the thickness of the buffer oxide film is set 100 Å. Referring to FIG. 3, it should be noted that, while the fault ratio is 10.99% in the case that the target of the pre-cleaning process is set 200 Å, it decreases to 7.55% in the case that the target of the pre-cleaning process is set 150 Å. Further, Table 1 indicates word line fault ratios when the target of the pre-cleaning process is set 260 Å, 200 Å, 150 Å and 140 Å, respectively. As shown in Table 1, when the target of the pre-cleaning process is set 140 Å, the fault ratio is 5.2%.

TABLE 1

| Target of pre- | |
|---|---|
| cleaning process (Å) | Word line fault ratio (%) |
| 260 | 12.1 |
| 200 | 10.2 |
| 150 | 7.55 |
| 140 | 5.2 |

It is believed that the reason why the word line fault ratio depends on the target of the pre-cleaning process is that when the target of the pre-cleaning process is formed excessively high, a potential dislocation or a dangling bond (outer-most electrons of silicon atoms, which do not finish the coupling completely) may affect the tunnel oxide film formed after the pre-cleaning process. In addition an active region of the silicon substrate, in particular, the region where the source line junction is formed, may be damaged.

It is further believed that the word line fault of flash memory devices may be prevented by changing the target in the pre-cleaning process to remove the buffer oxide film. By resetting the target in the pre-cleaning process only, it may be possible to enhance yields and performance of the flash memory device.

While the invention has been shown and described with respect to the preferred embodiments, it will be understood by those skilled in the art that various changes and modifications may be made without departing from the spirit and scope of the invention as defined in the following claims.

What is claimed is:

1. A method for fabricating a flash memory device, comprising:
forming a buffer film on a semiconductor substrate having a defined active region;
controlling a threshold voltage of a memory cell by ion-implanting dopants into the active region of the substrate under the buffer film;
removing the buffer film by performing a wet cleaning process whose target thickness is about 1 to about 1.5 times the buffer film thickness; and
forming a tunnel dielectric film on the active region of the exposed substrate after the buffer film is removed.

2. The method of claim 1, wherein when the buffer film is removed, a portion of the substrate also is removed.

3. The method of claim 1, wherein the target thickness is about 1.4 times the buffer film thickness.

4. The method of claim 1, wherein the wet-cleaning process is performed by removing the buffer film using DHF and applying a COM cleaning process.

5. The method of claim 3, wherein the wet-cleaning process is performed by removing the buffer film using DHF and applying a COM cleaning process.

6. The method of one of claims 1, wherein the substrate is formed of silicon, and the buffer film is formed of a silicon oxide film.

7. The method of one of claims 3, wherein the substrate is formed of silicon, and the buffer film is formed of a silicon oxide film.

8. The method of claim 6, wherein the tunnel dielectric film is formed of a silicon oxide film.

9. The method of claim 7, wherein the tunnel dielectric film is formed of a silicon oxide film.
